(19) United States
(12) Patent Application Publication
(10) Pub. No.: US 2026/0153950 A1
(43) Pub. Date: Jun. 4, 2026

(54) METHOD AND APPARATUS FOR CALIBRATING CAPACITIVE STYLUS MODE, CAPACITIVE STYLUS, AND STORAGE MEDIUM

(71) Applicant: SHENZHEN QIANFENYI INTELLIGENT TECHNOLOGY CO., LTD, Shenzhen (CN)

(72) Inventors: Hongyao ZHONG, Shenzhen (CN); Zhuojun LI, Shenzhen (CN); Jian HUANG, Shenzhen (CN)

(73) Assignee: SHENZHEN QIANFENYI INTELLIGENT TECHNOLOGY CO., LTD, Shenzhen (CN)

(21) Appl. No.: 19/401,282

(22) Filed: Nov. 25, 2025

(30) Foreign Application Priority Data
Nov. 29, 2024 (CN) 202411741049.2

(51) Int. Cl. G06F 3/038; G01R 33/02; G01R 33/07; G06F 3/0338; G06F 3/0354

(52) U.S. Cl. CPC G06F 3/0383; G06F 3/0338; G06F 3/03545; G01R 33/0206; G01R 33/072

(57) ABSTRACT

A method for calibrating a capacitive stylus mode includes: respectively obtaining a first magnetic field strength, a second magnetic field strength, a third magnetic field strength and a fourth magnetic field strength; respectively calculating, based on the magnetic field strength, a first angle value and a second angle value of the 3D Hall switch when the stylus cap is rotated to the first switch position and the second switch position; obtaining a first threshold angle and a second threshold angle; updating an angle range of the first mode, an angle range of the second mode and an angle range of the third mode.

### CROSS-REFERENCE TO RELATED APPLICATIONS

This application claims priority to Chinese Patent Application No. 202411741049.2, filed on Nov. 29, 2024, the entire contents of which are incorporated herein by reference.

### TECHNICAL FIELD

The present application relates to the technical field of capacitive stylus, and in particular relates to a method and an apparatus for calibrating a capacitive stylus mode, a capacitive stylus, and a storage medium.

### BACKGROUND

With the continuous advancement of electronic technology and the popularization of smart devices, capacitive styluses, as an important input tool, have gained widespread application in various fields, including drawing, handwriting, and gaming. To meet diverse user needs, capacitive stylus designs are increasingly becoming multifunctional, with the ability to switch between three or more operating modes becoming a key design trend. However, in the field of capacitive stylus design, designers face numerous challenges: they need to meet users' needs for switching between three different operating modes, while at the same time implementing this mode switching function within the limited printed circuit board (PCB) space while taking into account the rotational appearance design of the capacitive stylus. This requires not only advanced circuit design skills but also ingenious structural design.

A key step in switching modes for a capacitive stylus is rotating the stylus cap to change the state of an internal switch, thereby switching between different operating modes. However, due to the varying rotation angles and certain angle jumps, this brings great difficulties to the precise control of hardware. This angle uncertainty may result in unintended triggering, or fail to operate as intended, severely impacting the stability and user experience of the capacitive stylus. Specifically, when rotating the stylus cap to switch modes, if the angle jump exceeds the designed range, the internal switch may malfunction, causing the capacitive stylus to switch to the incorrect operating mode. Conversely, if the angle jump is insufficient, the switch may not be triggered, preventing the capacitive stylus from switching to the intended operating mode. Both of these situations can cause unnecessary inconvenience to the user and degrade the performance of the capacitive stylus.

Therefore, how to accurately switch between multiple operating modes while maintaining the rotational appearance design of the capacitive stylus has become an urgent technical problem to be solved in the current field of capacitive stylus.

### SUMMARY

The main purpose of the present application is to provide a mode calibration method and device for a capacitive stylus, a capacitive stylus and a storage medium, aiming to achieve accurate switching of multiple operating modes of the capacitive stylus.

To achieve the above-mentioned object, the present application proposes a method for calibrating a capacitive stylus mode, including:
determining a first rotation angle value when a stylus cap is rotated to a first switch position and a second rotation angle value when the stylus cap is rotated to a second switch position;
calculating a sum of the first rotation angle value and a preset calibration value and saving the sum of the first rotation angle value and the preset calibration value as a first threshold angle; calculating a difference between the second rotation angle value and a preset calibration value and saving the difference between the second rotation angle value and the preset calibration value as a second threshold angle, the first threshold angle is less than the second threshold angle; and
updating an angle range of a first mode to include angles less than or equal to the first threshold angle, updating an angle range of a second mode to include angles greater than the first threshold angle and less than the second threshold angle, and updating an angle range of a third mode to include angles greater than or equal to the second threshold angle.

In an embodiment, the capacitive stylus includes a Hall sensor component, the determining the first rotation angle value when the stylus cap is rotated to the first switch position and the second rotation angle value when the stylus cap is rotated to the second switch position includes:
obtaining a first magnetic field signal detected by the Hall sensor component when the stylus cap is rotated to the first switch position, and determining the first rotation angle value when the stylus cap is rotated to the first switch position based on the first magnetic field signal; and
obtaining a second magnetic field signal detected by the Hall sensor component when the stylus cap is rotated to the second switch position, and determining the second rotation angle value when the stylus cap is rotated to the second switch position based on the second magnetic field signal.

In an embodiment, the Hall sensor component is a 3D Hall switch, the obtaining the first magnetic field signal detected by the Hall sensor component when the stylus cap is rotated to the first switch position, and determining the first rotation angle value when the stylus cap is rotated to the first switch position based on the first magnetic field signal; and obtaining the second magnetic field signal detected by the Hall sensor component when the stylus cap is rotated to the second switch position, and determining the second rotation angle value when the stylus cap is rotated to the second switch position based on the second magnetic field signal, includes:
obtaining a first magnetic field strength in a first direction and a second magnetic field strength in a second direction of the 3D Hall switch when the stylus cap is rotated to the first switch position, and obtaining a third magnetic field strength in the first direction and a fourth magnetic field strength in the second direction of the 3D Hall switch when the stylus cap is rotated to the second switch position, the first direction is orthogonal to the second direction;
calculating a first angle value of the 3D Hall switch when the stylus cap is rotated to the first switch position according to the first magnetic field strength and the second magnetic field strength, and calculating a second angle value of the 3D Hall switch when the stylus cap is rotated to the second switch position according to the third magnetic field strength and the fourth magnetic field strength, the first angle value is less than the second angle value; and
determining the first angle value as the first rotation angle value, and determining the second angle value as the second rotation angle value.

In an embodiment, the calculating the first rotation angle value of the 3D Hall switch when the stylus cap is rotated to the first switch position according to the first magnetic field strength and the second magnetic field strength, and calculating the second rotation angle value of the 3D Hall switch when the stylus cap is rotated to the second switch position according to the third magnetic field strength and the fourth magnetic field strength includes:
calculating a first angle parameter based on the first magnetic field strength and the second magnetic field strength, and calculating a second angle parameter based on the third magnetic field strength and the fourth magnetic field strength; and
performing inverse trigonometric function calculations on the first angle parameter and the second angle parameter respectively to obtain the first rotation angle value and the second rotation angle value.

In an embodiment, the calculating the sum of the first rotation angle value and the preset calibration value and saving the sum of the first rotation angle value and the preset calibration value as the first threshold angle; calculating the difference between the second rotation angle value and the preset calibration value and saving the difference between the second rotation angle value and the preset calibration value as the second threshold angle includes:
obtaining a plurality of first rotation angle values and a plurality of second rotation angle values for a preset count;
comparing the plurality of first rotation angle values to obtain a maximum first rotation angle value, and comparing the plurality of second rotation angle values to obtain a minimum second rotation angle value; and
calculating a sum of the maximum first rotation angle value and the preset calibration value and saving the sum of the maximum first rotation angle value and the preset calibration value as the first threshold angle; calculating a difference between the minimum second rotation angle value and the preset calibration value and saving the difference between the minimum second rotation angle value and the preset calibration value as the second threshold angle, the first threshold angle is less than the second threshold angle.

In an embodiment, the preset calibration value includes a first calibration value and a second calibration value that increase in sequence, and after the obtaining the plurality of first rotation angle values and the plurality of second rotation angle values for the preset count, the method further includes:
comparing the plurality of first rotation angle values to obtain the maximum first rotation angle value and a minimum first rotation angle value, and comparing the plurality of second rotation angle values to obtain a maximum second rotation angle value and the minimum second rotation angle value;
calculating a difference between the maximum first rotation angle value and the minimum first rotation angle value to obtain a first angle difference, and calculating a difference between the maximum second rotation angle value and the minimum second rotation angle value to obtain a second angle difference; and
using a larger of the first angle difference and the second angle difference as a deviation value, in response to that the deviation value is less than a preset deviation threshold, using the first calibration value as the preset calibration value, and in response to that the deviation value is greater than or equal to the preset deviation threshold, using the second calibration value as the preset calibration value.

In an embodiment, operating modes of the capacitive stylus include an air mouse mode, a laser mode, and a writing mode.

The present application further provides an apparatus for calibrating a capacitive stylus mode, the apparatus includes a memory, a processor, and a computer program stored in the memory and executable on the processor, the computer program is configured to implement the method for calibrating the capacitive stylus mode as described above.

The present application further provides a capacitive stylus, including:
the apparatus for calibrating a capacitive stylus mode as described above;
a stylus cap; and
a stylus body;
the stylus cap is provided at the stylus body and is configured rotate around an axis of the stylus body to switch operating modes.

In an embodiment, the capacitive stylus includes a Hall sensor component, the Hall sensor component is configured to sense magnetic field changes generated when the stylus cap is rotated and output corresponding magnetic field signals.

In an embodiment, the apparatus for calibrating the capacitive stylus mode is further configured to:
obtain a first magnetic field signal detected by the Hall sensor component when the stylus cap is rotated to the first switch position, and determine the first rotation angle value when the stylus cap is rotated to the first switch position based on the first magnetic field signal; and
obtain a second magnetic field signal detected by the Hall sensor component when the stylus cap is rotated to the second switch position, and determine the second rotation angle value when the stylus cap is rotated to the second switch position based on the second magnetic field signal;
calculate a sum of the first rotation angle value and a preset calibration value and save the sum of the first rotation angle value and the preset calibration value as a first threshold angle; calculate a difference between the second rotation angle value and a preset calibration value and save the difference between the second rotation angle value and the preset calibration value as a second threshold angle, the first threshold angle is less than the second threshold angle; and
update an angle range of a first mode to include angles less than or equal to the first threshold angle, update an angle range of a second mode to include angles greater than the first threshold angle and less than the second threshold angle, and update an angle range of a third mode to include angles greater than or equal to the second threshold angle.

In an embodiment, the Hall sensor component includes a permanent magnet portion and a sensing portion, one of the permanent magnet portion and the sensing portion is provided at the stylus cap, the other is provided at the stylus body, the sensing portion is configured to sense magnetic field changes generated when the sensing portion rotates relative to the permanent magnet portion and output corresponding magnetic field signals.

In an embodiment, the permanent magnet portion is provided at the stylus cap, and the sensing portion is provided at the stylus body.

The present application further provides a non-transitory computer-readable storage medium, a computer program is stored on the computer-readable storage medium, and when the computer program is executed by a processor, the computer program is configured to implement the method for calibrating the capacitive stylus mode as described above.

The technical solution of the present application obtains the rotation angle values when the stylus cap is rotated to different switch positions, and determines the angle ranges of different modes based on these angle values and preset calibration values, thereby accurately calibrating the capacitive stylus mode and achieving precise switching of multiple operating modes of the capacitive stylus while ensuring the rotational appearance design of the capacitive stylus.

### BRIEF DESCRIPTION OF THE DRAWINGS

In order to more clearly illustrate the embodiments of the present application or the technical solutions in the related art, the following briefly introduces the drawings required for use in the embodiments or the description of the related art. Obviously, the drawings described below are only some embodiments of the present application. For those skilled in the art, other drawings can be obtained based on the structures shown in these drawings without paying any creative work.

FIG. 1 is a flow chart of a method for calibrating a capacitive stylus mode according to a first embodiment of the present application.

FIG. 2 is a flow chart of the method for calibrating the capacitive stylus mode according to a second embodiment of the present application.

FIG. 3 is a flow chart of the method for calibrating the capacitive stylus mode according to a third embodiment of the present application.

FIG. 4 is a flow chart of the method for calibrating the capacitive stylus mode according to a fourth embodiment of the present application.

FIG. 5 is a flow chart of the method for calibrating the capacitive stylus mode according to a fifth embodiment of the present application.

FIG. 6 is a schematic diagram of an angle range of various modes in the method for calibrating the capacitive stylus mode according to an embodiment of the present application.

FIG. 7 is a schematic diagram of an apparatus for calibrating a capacitive stylus mode according to an embodiment of the present application.

The purpose, features and advantages of the present application will be further described with reference to the accompanying drawings and in conjunction with the embodiments.

### DETAILED DESCRIPTION OF THE EMBODIMENTS

The following will clearly and completely describe the technical solutions in the embodiments of the present application in conjunction with the accompanying drawings. Obviously, the described embodiments are only part of the embodiments of the present application, not all of the embodiments. Based on the embodiments of the present application, all other embodiments obtained by those skilled in the art without making any creative efforts shall fall within the scope of protection of the present application.

It should be noted that if the embodiments of the present application involve directional indications (such as up, down, left, right, front, back, etc.), the directional indications are only used to explain the relative position relationship, movement status, etc. between the various components under a certain specific posture. If the specific posture changes, the directional indications will also change accordingly.

In addition, if there are descriptions involving “first”, “second”, etc. in the embodiments of the present application, the descriptions of “first”, “second”, etc. are only for descriptive purposes and cannot be understood as indicating or suggesting their relative importance or implicitly indicating the number of the indicated technical features. Therefore, the features limited to “first” and “second” may explicitly or implicitly include at least one of such features. In addition, if “and/or” or “and/or” appears in the full text, its meaning includes three parallel solutions. Taking “A and/or B” as an example, it includes solution A, solution B, or solutions that satisfy both A and B. In addition, the technical solutions between the various embodiments can be combined with each other, but it must be based on the ability of those skilled in the art to implement. When the combination of technical solutions is mutually contradictory or cannot be implemented, it should be deemed that such a combination of technical solutions does not exist and is not within the scope of protection required by the present application.

With the continuous advancement of electronic technology and the popularization of smart devices, capacitive styluses, as an important input tool, have gained widespread application in various fields, including drawing, handwriting, and gaming. To meet diverse user needs, capacitive stylus designs are increasingly becoming multifunctional, with the ability to switch between three or more operating modes becoming a key design trend. However, in the field of capacitive stylus design, designers face many challenges: they need to meet users' needs for switching between three different operating modes, while at the same time implementing this mode switching function within the limited printed circuit board (PCB) space while taking into account the rotational appearance design of the capacitive stylus. This requires not only advanced circuit design skills but also ingenious structural design.

A key step in switching modes for a capacitive stylus is rotating the stylus cap to change the state of an internal switch, thereby switching between different operating modes. However, due to the varying rotation angles and certain angle jumps, this brings great difficulties to the precise control of hardware. This angle uncertainty can cause the switch to accidentally trigger when it shouldn't, or malfunction when it should, severely impacting the stability and user experience of the capacitive stylus. Specifically, when rotating the stylus cap to switch modes, if the angle jump exceeds the designed range, the internal switch may malfunction, preventing the capacitive stylus from switching to the user's desired operating mode. This can cause unnecessary inconvenience to the user and reduce the user experience of the capacitive stylus.

In order to overcome the above problems, the present application proposes a method for calibrating a capacitive stylus mode.

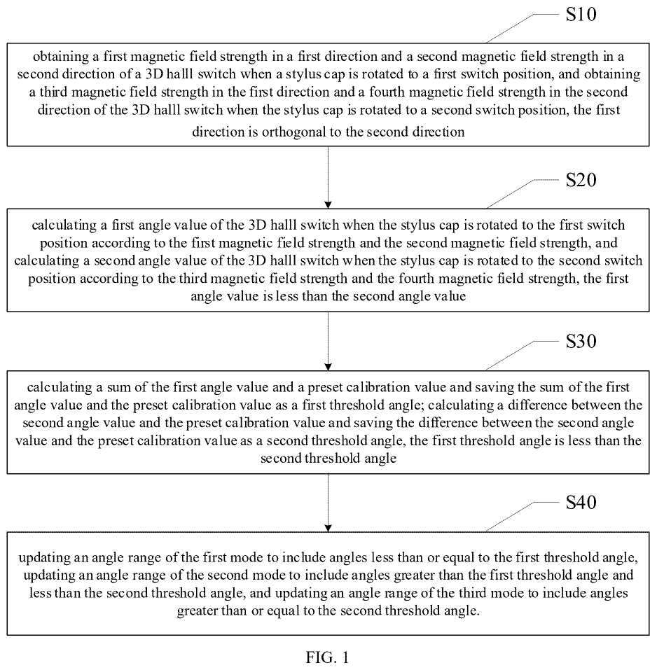

As shown in FIG. 1, in the first embodiment of the present application, the method for calibrating the capacitive stylus mode includes steps S10 to S40.

Step S10, obtaining a first magnetic field strength in a first direction and a second magnetic field strength in a second direction of a 3D Hall switch when a stylus cap is rotated to a first switch position, and obtaining a third magnetic field strength in the first direction and a fourth magnetic field strength in the second direction of the 3D Hall switch when the stylus cap is rotated to a second switch position, the first direction is orthogonal to the second direction.

It should be noted that a capacitive stylus includes a stylus cap, a stylus body, a controller, and a 3D Hall switch. Detecting the magnetic field strength of the 3D Hall switch is crucial to the calibration process. In an embodiment, the 3D Hall switch includes a permanent magnet portion and a sensing portion. The permanent magnet portion is located in the stylus cap, while the sensing portion is located in the stylus body. The sensing portion senses the magnetic field changes generated by the synchronous rotation of the permanent magnet portion when the stylus cap is rotated, and outputs a magnetic field detection signal. By detecting the magnetic field strength at different switch positions and calculating the corresponding angle values, precise positioning of the stylus cap at different rotation angles can be ensured.

The cap of the capacitive stylus can be rotated to switch between a first switch position, a second switch position, and a third switch position, the third switch position is located between the first switch position and the second switch position, corresponding to the angle range of the second mode R2. The first switch position is the switch position corresponding to when the cap of the capacitive stylus is rotated to the extreme position on the first side of the stylus body, corresponding to the angle range of the first mode R1 of the capacitive stylus. The second switch position is the switch position corresponding to when the cap of the capacitive stylus is rotated to the extreme position on the second side of the stylus body, corresponding to the angle range of the third mode R3 of the capacitive stylus.

Step S20, calculating a first angle value of the 3D Hall switch when the stylus cap is rotated to the first switch position according to the first magnetic field strength and the second magnetic field strength, and calculating a second angle value of the 3D Hall switch when the stylus cap is rotated to the second switch position according to the third magnetic field strength and the fourth magnetic field strength, the first angle value is less than the second angle value.

It should be noted that the correspondence between magnetic field strength and angle in the first and second directions is used to obtain the first angle value of the 3D Hall switch in the first switch position and the second angle value in the second switch position. The first and second angle values are angle values calculated based on magnetic field strength, not the actual physical angle values of the stylus cap rotation. This correspondence can be obtained through trigonometric functions or calibration, and is not specifically limited in the embodiment.

Step S30, calculating a sum of the first angle value and a preset calibration value and saving the sum of the first angle value and the preset calibration value as a first threshold angle; calculating a difference between the second angle value and the preset calibration value and saving the difference between the second angle value and the preset calibration value as a second threshold angle, the first threshold angle is less than the second threshold angle.

It should be noted that the preset calibration value is an angle value greater than the stylus cap rotation jump angle, and the first threshold angle D1 is the sum of the first angle value and the preset calibration value. The first threshold angle D1 must be greater than the angle when the stylus cap is rotated to the first switch position, and there is space reserved for angle jump, so that when the stylus cap is rotated to the first switch position, even if an angle jump occurs, the first angle value is always less than the first threshold angle D1. Similarly, by subtracting the second angle value from the preset calibration value, the second threshold angle D2 is obtained, so that when the stylus cap is rotated to the second switch position, the second angle value is always greater than the second threshold angle D2.

In addition, the preset calibration value should be set so that the first threshold angle D1 is smaller than the second threshold angle D2 to ensure that the angle range of the first mode R1 and the angle range of the third mode R3 do not overlap, and the angle range of the second mode R2 can be reserved.

Step S40, updating an angle range of the first mode to include angles less than or equal to the first threshold angle, updating an angle range of the second mode to include angles greater than the first threshold angle and less than the second threshold angle, and updating an angle range of the third mode to include angles greater than or equal to the second threshold angle.

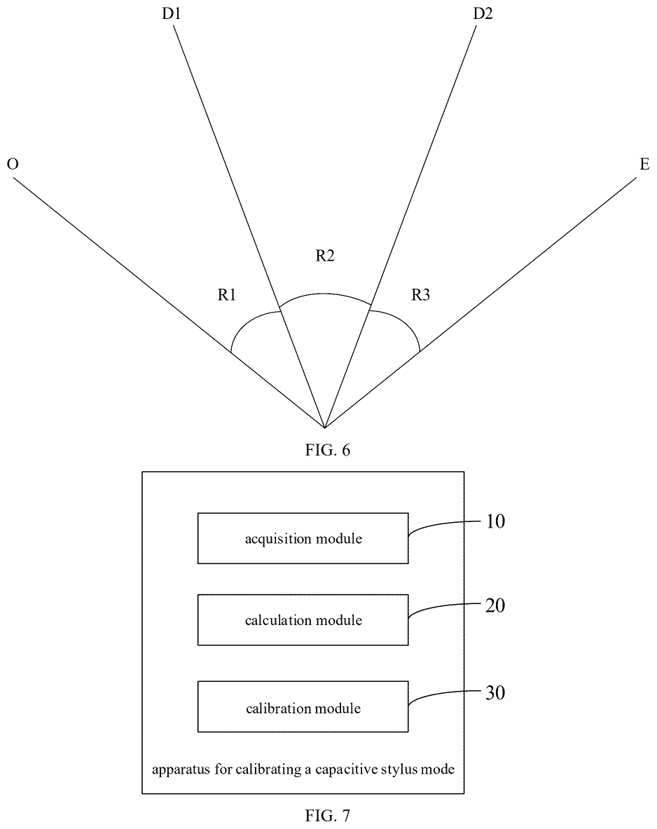

It should be noted that, as shown in FIG. 6, the angle range of the first mode R1, the angle range of the second mode R2 and the angle range of the third mode R3 are divided by the first threshold angle D1, the second threshold angle D2 and the initial angle O and the final angle E of the 3D Hall switch, where each angle range corresponds to a switch position of the capacitive stylus, so that when the cap of the capacitive stylus is rotated to different switch positions, even if an angle jump occurs, it can be in the corresponding mode angle range and accurately switch to the corresponding operating mode.

In the embodiment, by obtaining the magnetic field strength of the 3D Hall switch in different directions when the stylus cap is rotated to different switch positions, the corresponding angle values are calculated, and the angle ranges of different modes are determined based on these angle values and preset calibration values, thereby accurately calibrating the capacitive stylus mode and achieving the precise switching of multiple operating modes of the capacitive stylus while ensuring the rotational appearance design of the capacitive stylus.

It is understood that determining the first rotation angle value when the stylus cap is rotated to the first switch position and the second rotation angle value when the stylus cap is rotated to the second switch position can be achieved through the following steps: obtaining a first magnetic field signal detected by the Hall sensor component when the stylus cap is rotated to the first switch position, and determining the first rotation angle value when the stylus cap is rotated to the first switch position based on the first magnetic field signal; and obtaining a second magnetic field signal detected by the Hall sensor component when the stylus cap is rotated to the second switch position, and determining the second rotation angle value when the stylus cap is rotated to the second switch position based on the second magnetic field signal.

The determining the first and second rotation angle values can refer to steps S10 and S20, where the first rotation angle value is the same as the first angle value in step S20, and the second rotation angle value is the same as the second angle value in step S20. It is understood that the first angle value is equivalent to the first rotation angle value, and the second angle value is equivalent to the second rotation angle value, unless otherwise specified, the corresponding angle values can be understood equivalently. Furthermore, the Hall sensor component can be the 3D Hall switch used in the above embodiments.

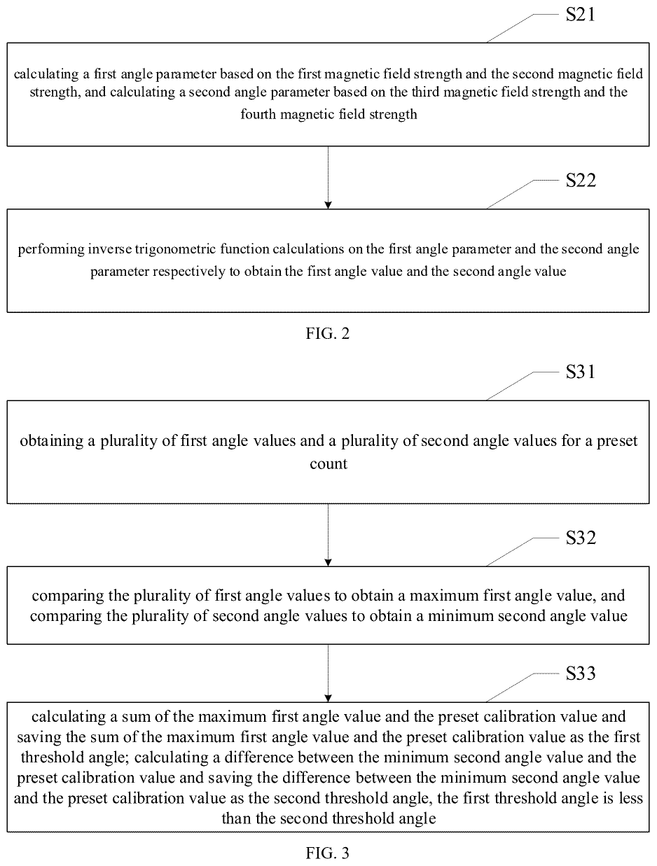

Based on the first embodiment of the present application, in the second embodiment of the present application, the same or similar contents as those in the first embodiment can be referred to above and will not be described in detail. On this basis, as shown in FIG. 2, in the second embodiment of the present application, step S20 may include steps S21 and S22.

Step S21, calculating a first angle parameter based on the first magnetic field strength and the second magnetic field strength, and calculating a second angle parameter based on the third magnetic field strength and the fourth magnetic field strength.

In an embodiment of the present application, the first angle parameter is a ratio of the first magnetic field strength to the second magnetic field strength, and the second angle parameter is a ratio of the third magnetic field strength to the fourth magnetic field strength.

Step S22, performing inverse trigonometric function calculations on the first angle parameter and the second angle parameter respectively to obtain the first angle value and the second angle value.

It should be noted that the controller of the capacitive stylus calculates the arctangent value of the first angle parameter to obtain the first angle value, and similarly, the arctangent value of the second angle parameter is calculated to obtain the second angle value. This allows the accurate calculation of the angle values of the capacitive stylus's 3D Hall switch at different switch positions when the stylus cap is rotated. The first and second angle parameters are calculated based on the magnetic field strength in the first and second directions, which are orthogonal to each other, and the detectable angle value can be expanded to 360°.

The present application uses 3D Hall switches and inverse trigonometric function calculation methods to accurately measure the angle values of 3D Hall switches at different switch positions. The present application can more accurately calculate the angle value of a capacitive stylus at different switch positions, thereby improving the stability and accuracy of the capacitive stylus when switching between different operating modes, ensuring that the capacitive stylus accurately switches to the intended operating mode when operated by the user.

Based on the first and/or second embodiments of the present application, in the third embodiment of the present application, the same or similar contents as those of the first and second embodiments can be referred to above and will not be described in detail. On this basis, as shown in FIG. 3, in the third embodiment of the present application, step S30 may include steps S31 to S33.

Step S31, obtaining a plurality of first angle values and a plurality of second angle values for a preset count.

It should be noted that obtaining a plurality of first angle values and a plurality of second angle values for a preset count can reduce the error of a single measurement, thereby improving data accuracy. In an embodiment of the present application, the preset count can be set to 5. The greater the preset count will increase the reliability of the obtained data results, but will also increase the duration required for the calibration process. The setting of the preset count needs to be selected based on actual calibration requirements and is not specifically limited in the embodiment.

Step S32, comparing the plurality of first angle values to obtain a maximum first angle value, and comparing the plurality of second angle values to obtain a minimum second angle value.

Step S33, calculating a sum of the maximum first angle value and the preset calibration value and saving the sum of the maximum first angle value and the preset calibration value as the first threshold angle; calculating a difference between the minimum second angle value and the preset calibration value and saving the difference between the minimum second angle value and the preset calibration value as the second threshold angle, the first threshold angle is less than the second threshold angle.

It should be noted that, calculation with the maximum first angle value can make the final first threshold angle D1 the maximum value, so that the first threshold angle D1 is greater than all first angle values, so that when the stylus cap is rotated to the first switch position, even if an angle jump occurs, the first angle value is always less than the first threshold angle D1. Similarly, calculation with the minimum first angle value can make the final second threshold angle D2 the minimum value, so that the second threshold angle D2 is less than all second angle values, so that when the stylus cap is rotated to the second switch position, even if an angle jump occurs, the second angle value is always greater than the second threshold angle D2.

In the embodiments of the present application, by obtaining and comparing a plurality of first angle values and a plurality of second angle values a preset count, and selecting the maximum first angle value and the minimum second angle value to calculate the first threshold angle D1 and the second threshold angle D2, the accuracy and reliability of the data can be effectively improved. This ensures that the mode switching of the capacitive stylus is not affected by angle jumps during rotation, further ensuring that the capacitive stylus can accurately switch between different modes.

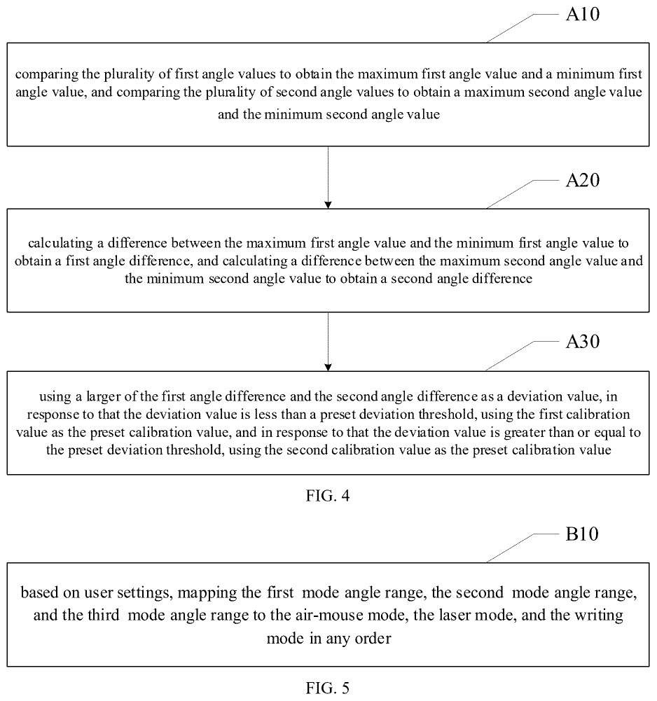

Based on the above embodiments of the present application, in the fourth embodiment of the present application, the same or similar contents as the above embodiments can be referred to the above description and will not be repeated hereafter. On this basis, as shown in FIG. 4, in the fourth embodiment of the present application, the preset calibration value includes a first calibration value and a second calibration value that increase in sequence. After step S31, steps A10 to A30 may also be included.

Step A10, comparing the plurality of first angle values to obtain the maximum first angle value and a minimum first angle value, and comparing the plurality of second angle values to obtain a maximum second angle value and the minimum second angle value;

Step A20, calculating a difference between the maximum first angle value and the minimum first angle value to obtain a first angle difference, and calculating a difference between the maximum second angle value and the minimum second angle value to obtain a second angle difference; and

Step A30, using a larger of the first angle difference and the second angle difference as a deviation value, in response to that the deviation value is less than a preset deviation threshold, using the first calibration value to the preset calibration value, and in response to that the deviation value is greater than or equal to the preset deviation threshold, using the second calibration value to the preset calibration value.

It should be noted that by comparing a plurality of first angle values with a plurality of second angle values and calculating the range of the plurality of first angle values and the multiple second angle values, the larger of the two values can be used as the deviation value to characterize the angle jump when the capacitive stylus switches the operating mode. The preset standard value is determined according to the deviation value. When the deviation value is less than the preset deviation threshold, it means that the angle jump amplitude is small, and the calibration requirement can be met by using the first calibration value as the preset calibration value. When the deviation value is greater than the preset deviation threshold, it means that the angle jump amplitude is large, and the calibration requirement can be met by using a second calibration value (greater than the first calibration value) as the preset calibration value. In an embodiment of the present application, the first calibration value can be set to 15°, the second calibration value can be set to 20°, and the preset deviation threshold can be set to 6°. The settings of the first calibration value, the second calibration value, and the preset deviation threshold need to be matched and set according to the actual test situation to meet the calibration requirement. The embodiment does not limit this.

The embodiment of the present application obtains the maximum angle deviation value by obtaining a plurality of angle values for a preset count, and then determines the preset calibration value as the one that is more in line with the standard between the first and second calibration values for calibration. This effectively adjusts and optimizes the calibration accuracy of the capacitive stylus's mode switching, resolving the problem of the calibration level not matching the deviation level during calibration. This improves the stability of the capacitive stylus and user experience, making the switching of the capacitive stylus between various operating modes more accurate and reliable.

Based on the above embodiments of the present application, in the fifth embodiment of the present application, the same or similar contents as those in the above embodiments can be referred to above and will not be described in detail. On this basis, in the fifth embodiment of the present application, the operating modes of the capacitive stylus include air mouse mode, laser mode, and writing mode.

In an embodiment, the three operating modes can be achieved by setting different circuit modules and sensors inside the capacitive stylus. For example, in the air mouse mode, the movement of the stylus can be detected by the built-in gyroscope and acceleration sensor, thereby realizing the movement of the mouse pointer. In the laser mode, the laser pointing function can be realized by integrating a laser emitter at the stylus tip. In the writing mode, the contact between the stylus tip and the screen can be detected by a capacitive sensor, thereby realizing the writing function. Furthermore, in an embodiment of the present application, the stylus cap is rotated to switch between different operating modes, and each operating mode corresponds to a different angle range, thereby realizing precise switching of modes.

The present application improves the practicality of the capacitive stylus and user experience by designing it to be able to switch between air mouse mode, laser mode and writing mode, and meets the diverse needs of users in different application scenarios.

As shown in FIG. 5, in an embodiment, after step S40, step B10 may be included:
B10, based on user settings, mapping the first mode angle range, the second mode angle range, and the third mode angle range to the air-mouse mode, the laser mode, and the writing mode in any order.

In an embodiment, users can use the settings interface to define the operating modes corresponding to the angle range of the first mode R1, the angle range of the second mode R2, and the angle range of the third mode R3. For example, users can choose to set the range less than or equal to the first threshold angle D1 as air mouse mode, the range greater than the first threshold angle D1 and less than the second threshold angle D2 as laser mode, and the range greater than or equal to the second threshold angle D2 as writing mode. This setting method allows users to flexibly adjust the corresponding angle ranges for each mode based on their usage habits and needs.

By setting the angle range of the first mode R1, the angle range of the second mode R2, and the angle range of the third mode R3 to correspond to one of the air mouse mode, laser mode, and writing mode, respectively, this solves the problem that the multiple modes of the capacitive stylus can only correspond to a fixed angle range and cannot be adjusted by the user. By mapping different angle ranges to different operating modes based on user-defined settings, the stylus cap can be precisely switched to the desired mode when it is rotated, thereby enhancing the diversity of capacitive stylus usage and user experience.

Through user-defined settings, the capacitive stylus can precisely switch to the desired operating mode when the stylus cap is rotated, avoiding issues such as malfunction or failure to trigger due to angle jumps. This not only improves the stability and accuracy of the capacitive stylus, but also enhances the user experience, allowing the capacitive stylus to perform optimally in different application scenarios.

In summary, the present application proposes a method for calibrating the capacitive stylus mode. This method obtains the magnetic field strength of the 3D Hall switch in the orthogonal direction when the stylus cap is rotated to different switch positions, calculates the corresponding angle value, and adjusts it according to the preset calibration value to determine different threshold angles and angle ranges at different modes, thereby achieving accurate switching between different modes of the capacitive stylus. This method can effectively solve the problem of malfunction or failure to switch normally due to rotation angle jumps, and ensure the stability and accuracy of the capacitive stylus when switching between different operating modes.

As shown in FIG. 7, the present application further provides an apparatus for calibrating a capacitive stylus mode, the apparatus for calibrating a capacitive stylus mode including: an acquisition module 10, a calculation module 20, and a calibration module 30.

The acquisition module 10 is configured to obtain a first magnetic field strength in a first direction and a second magnetic field strength in a second direction of a 3D Hall switch when a stylus cap is rotated to a first switch position, and obtain a third magnetic field strength in the first direction and a fourth magnetic field strength in the second direction of the 3D Hall switch when the stylus cap is rotated to a second switch position, the first direction is orthogonal to the second direction.

The calculation module 20 is configured to calculate a first angle value of the 3D Hall switch when the stylus cap is rotated to the first switch position according to the first magnetic field strength and the second magnetic field strength, and calculate a second angle value of the 3D Hall switch when the stylus cap is rotated to the second switch position according to the third magnetic field strength and the fourth magnetic field strength, the first angle value is less than the second angle value; calculate a sum of the first angle value and a preset calibration value and save the sum of the first angle value and the preset calibration value as a first threshold angle; calculate a difference between the second angle value and the preset calibration value and save the difference between the second angle value and the preset calibration value as a second threshold angle, the first threshold angle is less than the second threshold angle.

The calibration module 30 is configured to update an angle less than or equal to the first threshold angle to an angle range of the first mode, update an angle greater than the first threshold angle and less than the second threshold angle to an angle range of the second mode, and update an angle greater than or equal to the second threshold angle to an angle range of the third mode.

The apparatus for calibrating the capacitive stylus mode provided in an embodiment of the present application utilizes the method for calibrating a capacitive stylus mode described in the aforementioned embodiment to address the technical problem of accurately switching between multiple operating modes of a capacitive stylus while maintaining its rotational appearance design. Compared to the related art, the apparatus for calibrating the capacitive stylus mode provided in an embodiment of the present application has the same beneficial effects as the method for calibrating the capacitive stylus mode described in the aforementioned embodiment. Other technical features of the apparatus for calibrating the capacitive stylus mode are the same as those disclosed in the aforementioned embodiment and are not further elaborated here.

The present application further proposes an apparatus for calibrating a capacitive stylus mode, including a memory, a processor, and a computer program stored in the memory and executable on the processor. The computer program is configured to: determine a first rotation angle value when a stylus cap is rotated to a first switch position and a second rotation angle value when the stylus cap is rotated to a second switch position; calculate a sum of the first rotation angle value and a preset calibration value and save the sum of the first rotation angle value and the preset calibration value as a first threshold angle; calculate a difference between the second rotation angle value and a preset calibration value and save the difference between the second rotation angle value and the preset calibration value as a second threshold angle, the first threshold angle is less than the second threshold angle; and update an angle range of a first mode to include angles less than or equal to the first threshold angle, update an angle range of a second mode to include angles greater than the first threshold angle and less than the second threshold angle, and update an angle range of a third mode to include angles greater than or equal to the second threshold angle.

Therefore, the apparatus for calibrating the capacitive stylus mode of the embodiment obtains the rotation angle values when the stylus cap is rotated to different switch positions, and determines the angle ranges of different modes based on these angle values and preset calibration values, thereby accurately calibrating the capacitive stylus mode and achieving precise switching of multiple operating modes of the capacitive stylus while ensuring the rotational appearance design of the capacitive stylus.

It should be noted that the apparatus for calibrating the capacitive stylus mode can realize the method for calibrating the capacitive stylus mode in all the above embodiments, and therefore has at least all the beneficial effects of the method for calibrating the capacitive stylus mode in the above embodiments, which will not be described in detail here.

The present application further provides a capacitive stylus, including: a stylus cap, a stylus body, a 3D Hall switch and an apparatus for calibrating the capacitive stylus mode.

The 3D Hall switch includes a permanent magnet portion and a sensing portion, one of the permanent magnet portion and the sensing portion is provided at the stylus cap, the other is provided at the stylus body. For example, the permanent magnet portion is provided at the stylus cap, the sensing portion is provided at the stylus body, the sensing portion is configured to sense magnetic field changes generated when the stylus cap is rotated and output magnetic field detection signals.

The apparatus for calibrating the capacitive stylus mode is configured to execute the method for calibrating a capacitive stylus mode as described in any one of the above.

In an embodiment, the stylus cap is provided at the stylus body and is configured rotate around an axis of the stylus body to switch operating modes.

The capacitive stylus provided in the embodiments of the present application solves the technical problem of accurately switching between multiple operating modes while maintaining its rotational appearance design. Compared to the related art, the capacitive stylus provided in the embodiments of the present application has the same beneficial effects as the method for calibrating a capacitive stylus mode provided in the aforementioned embodiments, and will not be further elaborated here.

The present application further provides a computer-readable storage medium having computer-readable program instructions (i.e., a computer program) stored thereon, the computer-readable program instructions are used to execute the mode method for calibrating the capacitive stylus mode in the above embodiment.

The computer-readable storage medium provided herein may be, for example, a USB flash drive, but is not limited to electrical, magnetic, optical, electromagnetic, infrared, or semiconductor systems, systems, or devices, or any combination thereof. More specific examples of computer-readable storage media may include, but are not limited to, an electrical connection having one or more wires, a portable computer disk, a hard disk, random access memory (RAM), read-only memory (ROM), erasable programmable read-only memory (EPROM or flash memory), optical fiber, a portable compact disk read-only memory (CD-ROM), an optical storage device, a magnetic storage device, or any suitable combination thereof. In the embodiment, the computer-readable storage medium may be any tangible medium that contains or stores a program that can be used by or in conjunction with an instruction execution system, system, or device. The program code contained on the computer-readable storage medium may be transmitted using any suitable medium, including, but not limited to, wires, optical cables, radio frequency (RF), etc., or any suitable combination thereof.

The computer-readable storage medium may be included in the capacitive stylus, or may exist independently without being assembled into the capacitive stylus.

The computer-readable storage medium carries one or more programs. When the one or more programs are executed by the capacitive stylus, the capacitive stylus: obtaining a first magnetic field strength in a first direction and a second magnetic field strength in a second direction of a 3D Hall switch when a stylus cap is rotated to a first switch position, and obtaining a third magnetic field strength in the first direction and a fourth magnetic field strength in the second direction of the 3D Hall switch when the stylus cap is rotated to a second switch position, the first direction is orthogonal to the second direction; calculating a first angle value of the 3D Hall switch when the stylus cap is rotated to the first switch position according to the first magnetic field strength and the second magnetic field strength, and calculating a second angle value of the 3D Hall switch when the stylus cap is rotated to the second switch position according to the third magnetic field strength and the fourth magnetic field strength, the first angle value is less than the second angle value; calculating a sum of the first angle value and a preset calibration value and saving the sum of the first angle value and the preset calibration value as a first threshold angle; calculating a difference between the second angle value and the preset calibration value and saving the difference between the second angle value and the preset calibration value as a second threshold angle, the first threshold angle is less than the second threshold angle; and updating an angle less than or equal to the first threshold angle to an angle range of the first mode, updating an angle greater than the first threshold angle and less than the second threshold angle to an angle range of the second mode, and updating an angle greater than or equal to the second threshold angle to an angle range of the third mode.

Computer program code for performing the operations of the present application may be written in one or more programming languages, or a combination thereof, including object-oriented programming languages such as Java, Smalltalk, C++, and conventional procedural programming languages such as “C” or similar programming languages. The program code may be executed entirely on the user's computer, partially on the user's computer, as a stand-alone software package, partially on the user's computer and partially on a remote computer, or entirely on a remote computer or server. In the case of a remote computer, the remote computer may be connected to the user's computer via any type of network, including a local area network (LAN) or a wide area network (WAN), or may be connected to an external computer (e.g., via the Internet using an Internet service provider).

The flow charts and block diagrams in the accompanying drawings illustrate the possible architecture, functions and operations of the systems, methods and computer program products according to various embodiments of the present application. In this regard, each box in the flow chart or block diagram can represent a module, program segment or a part of code, and the module, program segment or a part of code contains one or more executable instructions for realizing the specified logical function. It should also be noted that in some alternative implementations, the functions marked in the box can also occur in a different order than that marked in the accompanying drawings. For example, two boxes represented in succession can actually be executed substantially in parallel, and they can sometimes be executed in the opposite order, depending on the functions involved. It should also be noted that each box in the block diagram and/or flow chart, and the combination of the boxes in the block diagram and/or flow chart can be implemented by a dedicated hardware-based system that performs the specified function or operation, or can be implemented by a combination of dedicated hardware and computer instructions.

The modules described in the embodiments of the present application may be implemented in software or hardware, the name of the module does not necessarily limit the unit itself.

The computer-readable storage medium provided in the present application stores computer-readable program instructions (i.e., a computer program) for executing the aforementioned method for calibrating a capacitive stylus mode. This computer-readable storage medium addresses the technical problem of accurately switching between various operating modes of a capacitive stylus while maintaining its rotational appearance design. Compared to the related art, the beneficial effects of the computer-readable storage medium provided in the present application are similar to those of the method for calibrating a capacitive stylus mode provided in the aforementioned embodiments, and are not further elaborated here.

The above description is merely an exemplary embodiment of the present application and does not limit the patent scope of the present application. Any equivalent structural transformation made by utilizing the contents of description and drawings of the present application under the technical concept of the present application, or directly/indirectly applied in other related technical fields, is included in the patent protection scope of the present application.

What is claimed is:

1. A method for calibrating a capacitive stylus mode, comprising:
determining a first rotation angle value when a stylus cap is rotated to a first switch position and a second rotation angle value when the stylus cap is rotated to a second switch position;
calculating a sum of the first rotation angle value and a preset calibration value and saving the sum of the first rotation angle value and the preset calibration value as a first threshold angle;
calculating a difference between the second rotation angle value and a preset calibration value and saving the difference between the second rotation angle value and the preset calibration value as a second threshold angle, wherein the first threshold angle is less than the second threshold angle; and
updating an angle range of a first mode to include angles less than or equal to the first threshold angle, updating an angle range of a second mode to include angles greater than the first threshold angle and less than the second threshold angle, and updating an angle range of a third mode to include angles greater than or equal to the second threshold angle.

2. The method for calibrating the capacitive stylus mode according to claim 1, wherein the capacitive stylus comprises a Hall sensor component, the determining the first rotation angle value when the stylus cap is rotated to the first switch position and the second rotation angle value when the stylus cap is rotated to the second switch position comprises:
obtaining a first magnetic field signal detected by the Hall sensor component when the stylus cap is rotated to the first switch position, and determining the first rotation angle value when the stylus cap is rotated to the first switch position based on the first magnetic field signal; and
obtaining a second magnetic field signal detected by the Hall sensor component when the stylus cap is rotated to the second switch position, and determining the second rotation angle value when the stylus cap is rotated to the second switch position based on the second magnetic field signal.

3. The method for calibrating the capacitive stylus mode according to claim 2, wherein the Hall sensor component is a 3D Hall switch, the obtaining the first magnetic field signal detected by the Hall sensor component when the stylus cap is rotated to the first switch position, and determining the first rotation angle value when the stylus cap is rotated to the first switch position based on the first magnetic field signal; and obtaining the second magnetic field signal detected by the Hall sensor component when the stylus cap is rotated to the second switch position, and determining the second rotation angle value when the stylus cap is rotated to the second switch position based on the second magnetic field signal, comprises:
obtaining a first magnetic field strength in a first direction and a second magnetic field strength in a second direction of the 3D Hall switch when the stylus cap is rotated to the first switch position, and obtaining a third magnetic field strength in the first direction and a fourth magnetic field strength in the second direction of the 3D Hall switch when the stylus cap is rotated to the second switch position, wherein the first direction is orthogonal to the second direction;
calculating a first angle value of the 3D Hall switch when the stylus cap is rotated to the first switch position according to the first magnetic field strength and the second magnetic field strength, and calculating a second angle value of the 3D Hall switch when the stylus cap is rotated to the second switch position according to the third magnetic field strength and the fourth magnetic field strength, wherein the first angle value is less than the second angle value; and
determining the first angle value as the first rotation angle value, and determining the second angle value as the second rotation angle value.

4. The method for calibrating the capacitive stylus mode according to claim 3, wherein the calculating the first rotation angle value of the 3D Hall switch when the stylus cap is rotated to the first switch position according to the first magnetic field strength and the second magnetic field strength, and calculating the second rotation angle value of the 3D Hall switch when the stylus cap is rotated to the second switch position according to the third magnetic field strength and the fourth magnetic field strength comprises:
calculating a first angle parameter based on the first magnetic field strength and the second magnetic field strength, and calculating a second angle parameter based on the third magnetic field strength and the fourth magnetic field strength; and
performing inverse trigonometric function calculations on the first angle parameter and the second angle parameter respectively to obtain the first rotation angle value and the second rotation angle value.

5. The method for calibrating the capacitive stylus mode according to claim 1, wherein the calculating the sum of the first rotation angle value and the preset calibration value and saving the sum of the first rotation angle value and the preset calibration value as the first threshold angle; calculating the difference between the second rotation angle value and the preset calibration value and saving the difference between the second rotation angle value and the preset calibration value as the second threshold angle comprises:
obtaining a plurality of first rotation angle values and a plurality of second rotation angle values for a preset count;
comparing the plurality of first rotation angle values to obtain a maximum first rotation angle value, and comparing the plurality of second rotation angle values to obtain a minimum second rotation angle value; and
calculating a sum of the maximum first rotation angle value and the preset calibration value and saving the sum of the maximum first rotation angle value and the preset calibration value as the first threshold angle; calculating a difference between the minimum second rotation angle value and the preset calibration value and saving the difference between the minimum second rotation angle value and the preset calibration value as the second threshold angle, wherein the first threshold angle is less than the second threshold angle.

6. The method for calibrating the capacitive stylus mode according to claim 5, wherein the preset calibration value comprises a first calibration value and a second calibration value that increase in sequence, and after the obtaining the plurality of first rotation angle values and the plurality of second rotation angle values for the preset count, the method further comprises:
comparing the plurality of first rotation angle values to obtain the maximum first rotation angle value and a minimum first rotation angle value, and comparing the plurality of second rotation angle values to obtain a maximum second rotation angle value and the minimum second rotation angle value;
calculating a difference between the maximum first rotation angle value and the minimum first rotation angle value to obtain a first angle difference, and calculating a difference between the maximum second rotation angle value and the minimum second rotation angle value to obtain a second angle difference; and
using a larger of the first angle difference and the second angle difference as a deviation value, in response to that the deviation value is less than a preset deviation threshold, using the first calibration value as the preset calibration value, and in response to that the deviation value is greater than or equal to the preset deviation threshold, using the second calibration value as the preset calibration value.

7. The method for calibrating the capacitive stylus mode according to claim 1, wherein operating modes of the capacitive stylus comprise an air mouse mode, a laser mode, and a writing mode.

8. The method for calibrating the capacitive stylus mode according to claim 7, wherein updating the angle less than or equal to the first threshold angle to the angle range of the first mode, updating the angle greater than the first threshold angle and less than the second threshold angle to the angle range of the second mode, and updating the angle greater than or equal to the second threshold angle to the angle range of the third mode, the method further comprises:
based on user settings, mapping the first mode angle range, the second mode angle range, and the third mode angle range to the air-mouse mode, the laser mode, and the writing mode in any order.

9. An apparatus for calibrating a capacitive stylus mode, wherein the apparatus comprises a memory, a processor, and a computer program stored in the memory and executable on the processor, the computer program is configured to:
determine a first rotation angle value when a stylus cap is rotated to a first switch position and a second rotation angle value when the stylus cap is rotated to a second switch position;
calculate a sum of the first rotation angle value and a preset calibration value and save the sum of the first rotation angle value and the preset calibration value as a first threshold angle; calculate a difference between the second rotation angle value and a preset calibration value and save the difference between the second rotation angle value and the preset calibration value as a second threshold angle, wherein the first threshold angle is less than the second threshold angle; and
update an angle range of a first mode to include angles less than or equal to the first threshold angle, update an angle range of a second mode to include angles greater than the first threshold angle and less than the second threshold angle, and update an angle range of a third mode to include angles greater than or equal to the second threshold angle.

10. A capacitive stylus, comprising:
the apparatus for calibrating the capacitive stylus mode according to claim 9;
a stylus cap; and
a stylus body;
wherein the stylus cap is provided at the stylus body and is configured rotate around an axis of the stylus body to switch operating modes.

11. The capacitive stylus according to claim 10, wherein the capacitive stylus comprises a Hall sensor component, the Hall sensor component is configured to sense magnetic field changes generated when the stylus cap is rotated and output corresponding magnetic field signals.

12. The capacitive stylus according to claim 11, wherein the apparatus for calibrating the capacitive stylus mode is further configured to:
obtain a first magnetic field signal detected by the Hall sensor component when the stylus cap is rotated to the first switch position, and determine the first rotation angle value when the stylus cap is rotated to the first switch position based on the first magnetic field signal; and
obtain a second magnetic field signal detected by the Hall sensor component when the stylus cap is rotated to the second switch position, and determine the second rotation angle value when the stylus cap is rotated to the second switch position based on the second magnetic field signal;
calculate a sum of the first rotation angle value and a preset calibration value and save the sum of the first rotation angle value and the preset calibration value as a first threshold angle; calculate a difference between the second rotation angle value and a preset calibration value and save the difference between the second rotation angle value and the preset calibration value as a second threshold angle, wherein the first threshold angle is less than the second threshold angle; and
update an angle range of a first mode to include angles less than or equal to the first threshold angle, update an angle range of a second mode to include angles greater than the first threshold angle and less than the second threshold angle, and update an angle range of a third mode to include angles greater than or equal to the second threshold angle.

13. The capacitive stylus according to claim 11, wherein the Hall sensor component comprises a permanent magnet portion and a sensing portion, one of the permanent magnet portion and the sensing portion is provided at the stylus cap, the other is provided at the stylus body, the sensing portion is configured to sense magnetic field changes generated when the sensing portion rotates relative to the permanent magnet portion and output corresponding magnetic field signals.

14. The capacitive stylus according to claim 13, wherein the permanent magnet portion is provided at the stylus cap, and the sensing portion is provided at the stylus body.

15. A non-transitory computer-readable storage medium, wherein a computer program is stored on the computer-readable storage medium, and when the computer program is executed by a processor, the computer program is configured to:
determine a first rotation angle value when a stylus cap is rotated to a first switch position and a second rotation angle value when the stylus cap is rotated to a second switch position;
calculate a sum of the first rotation angle value and a preset calibration value and save the sum of the first rotation angle value and the preset calibration value as a first threshold angle; calculate a difference between the second rotation angle value and a preset calibration value and save the difference between the second rotation angle value and the preset calibration value as a second threshold angle, wherein the first threshold angle is less than the second threshold angle; and
update an angle range of a first mode to include angles less than or equal to the first threshold angle, update an angle range of a second mode to include angles greater than the first threshold angle and less than the second threshold angle, and update an angle range of a third mode to include angles greater than or equal to the second threshold angle.
